(19) United States
(12) Patent Application Publication
(10) Pub. No.: US 2008/0184543 A1
(43) Pub. Date: Aug. 7, 2008

(54) METHOD AND APPARATUS FOR MANUFACTURING SEMICONDUCTOR DEVICE, AND STORAGE MEDIUM FOR EXECUTING THE METHOD

(75) Inventors: Takuji Sako, Yamanashi (JP); Yusaku Kashiwagi, Yamanashi (JP); Hiroyuki Toshima, Yamanashi (JP); Kaoru Maekawa, Albany, NY (US)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/024,445

(22) Filed: Feb. 1, 2008

(30) Foreign Application Priority Data
Feb. 2, 2007 (JP) 2007-024212

(51) Int. Cl. H01L 21/768; H01L 21/67

(52) U.S. Cl. 29/25.02; 438/659; 257/E21.584; 257/E21.001

(57) ABSTRACT

A semiconductor device manufacturing method capable of preventing an infliction of damage upon an interlayer insulating film and moisture adsorption thereto due to opening to atmosphere in a process of forming a CuSiN barrier by infiltrating Si into a surface of a copper-containing metal film and nitrifying a Si-infiltrated portion is disclosed.

When a semiconductor device is manufactured through the processes of preparing a semiconductor substrate having a copper-containing metal film exposed on a surface thereof; purifying a surface of the copper-containing metal film by using radicals or by using a thermo-chemical method; infiltrating Si into the surface of the copper-containing metal film; and nitrifying a Si-infiltrated portion of the copper-containing metal film by radicals, the purification process, the Si introduction process and the nitrification process are successively performed without breaking a vacuum.

### FIELD OF THE INVENTION

The present disclosure relates to a method and apparatus for manufacturing a semiconductor device having a copper-containing metal film, and a storage medium storing therein a program to be used in executing the manufacturing method.

### BACKGROUND OF THE INVENTION

To keep up with the recent trend for high-speed semiconductor devices having highly integrated and miniaturized wiring patterns, it is required to improve wiring conductivity. To meet such requirement, copper (Cu) is now attracting attention as a wiring material, for it has a higher conductivity than aluminum (Al) or tungsten (W).

However, since Cu is readily oxidized to form a fragile Cu oxide, deterioration of adhesivity and mechanical strength of wiring is highly likely to occur. Further, since Cu tends to diffuse easily, there is a high likelihood of an occurrence of electric conduction between wirings due to the diffusion of Cu into an interlayer insulating film. Conventionally, to solve the Cu oxidation and diffusion problems by way of enhancing a barrier property around a Cu wiring, a barrier metal such as Ta, TaN or the like is formed on a sidewall or a bottom portion of the Cu wiring, while a dielectric film such as SiN, SiCN, SiC, or the like, also serving as an etching stopper, is formed on a top surface of the Cu wiring.

In the aspect of realizing the miniaturization and the speed-up of the semiconductor devices, it has been attempted to reduce an inter-wiring capacitance and a dielectric constant of an interlayer insulating film. However, since the aforementioned SiN, SiCN, and SiC have high dielectric constants (SiN=7, SiCN=4.5, and SiC=3.5), using a dielectric barrier film having a lower dielectric constant is strongly required. Further, the mentioned barrier films need to have a film thickness larger than 30 nm in order to exert sufficient barrier property, thus impeding the miniaturization of the semiconductor devices.

To provide a solution to this problem, there is proposed a technique of forming CuSiN on a surface of a Cu wiring through the steps of loading, in a chamber, a semiconductor wafer having a Cu-containing metal film exposed on a surface thereof; performing a pre-treatment for removing an oxide film on a surface of the Cu-containing metal film by using a plasma; infiltrating Si into the surface of the Cu-containing metal film; and then nitrifying a portion of the Cu-containing film where the Si is infiltrated (see, for example, Patent Reference 1). By this technique, a barrier film can be formed only on the surface of Cu, and the dielectric barrier film can be formed to have a thin thickness. Further, even in case an etching stopper made of a SiC film or the like is formed on top of the barrier film, the total film thickness can be still kept thin, and the dielectric constant of the dielectric film on the surface of the Cu wiring can be reduced.

However, this technique also has drawbacks as follows. Since plasma is used in the pre-treatment and the nitrification process, damage is inflicted on the interlayer insulating film primarily by ions in the plasma. Particularly, when a low dielectric constant film (low-k film) is used as the interlayer insulating film, its film structure may be destructed, and due to opening to atmosphere, it would adsorb moisture, resulting in an increase of barrier property against the Cu wiring and an increase of dielectric constant and leakage current. Further, when an upper interlayer insulating film is formed on the interlayer insulating film, adhesivity therebetween may be deteriorated.
[Patent Reference 1]
Japanese Patent Laid-open Application No. 2006-237257

### BRIEF SUMMARY OF THE INVENTION

In view of the foregoing, the present invention provides a method and apparatus for manufacturing a semiconductor device, capable of preventing an infliction of damage upon an interlayer insulating film and moisture adsorption thereto due to opening to atmosphere in a process of forming a CuSiN barrier by infiltrating Si into a surface of a copper-containing metal film and nitrifying a Si-infiltrated portion.

Further, the present invention also provides a storage medium storing therein a program to be used in executing the semiconductor manufacturing method.

In accordance with a first aspect of the present invention, there is provided a method for manufacturing a semiconductor device including: preparing a semiconductor substrate having a copper-containing metal film exposed on a surface thereof; purifying a surface of the copper-containing metal film by using radicals or by using a thermo-chemical method; infiltrating Si into the surface of the copper-containing metal film; and nitrifying a Si-infiltrated portion of the copper-containing metal film by radicals, wherein the purification process, the Si infiltration process and the nitrification process are successively performed without breaking a vacuum.

In accordance with a second aspect of the present invention, there is provided a method for manufacturing a semiconductor device including: preparing a semiconductor substrate having a copper-containing metal film exposed on a surface thereof; purifying a surface of the copper-containing metal film by using radicals or by using a thermo-chemical method; infiltrating Si into the surface of the copper-containing metal film; nitrifying a Si-infiltrated portion of the copper-containing metal film by radicals; and forming a dielectric film on a nitride film formed by the nitrification process, wherein the purification process, the Si infiltration process, the nitrification process and the dielectric film formation process are successively performed without breaking a vacuum.

In the first aspect and second aspect of the present invention, the purification process may be performed by the radicals of a processing gas containing at least one of a H₂ gas, a N₂ gas, an Ar gas, and a NH₃ gas. At this time, the purification process can be performed by the radicals generated by converting the processing gas into a plasma by means of a microwave provided from a planar antenna having a number of slots or by the radicals generated by allowing the processing gas to contact with a high-temperature catalyst. Further, the thermo-chemical method for the purification process may be implemented by supplying a reducing gas to the surface of the copper-containing metal film while the semiconductor substrate is being heated.

Furthermore, in the first aspect and second aspect of the present invention, the nitrification process can be performed by using the radicals of an N-containing gas. At this time, the nitrification process may be performed by the radicals generated by converting the N-containing gas into a plasma by means of a microwave provided from a planar antenna having a number of slots or by the radicals generated by allowing the N-containing gas to contact with a high-temperature catalyst.

Moreover, in the first aspect and second aspect of the present invention, the series of the processes can be performed in the same chamber.

In addition, in the first aspect and second aspect of the present invention, the purification process and the Si infiltration process can be performed in a first chamber, while the other processes are performed in a second chamber, and, in the second aspect of the present invention, the purification process and the Si infiltration process may be performed in a first chamber, while the nitrification process and the dielectric film formation process may be performed in a second chamber.

Further, in the second aspect of the present invention, the purification process, the Si infiltration process and the nitrification process can be performed in a first chamber, while the dielectric film formation process can be performed in a second chamber. At this time, the first chamber has a function of generating the radicals by converting a gas for the purification process and a gas for the nitrification process into a plasma by means of a microwave provided from a planar antenna having a number of slots or a function of generating the radicals by allowing a gas for the purification process and a gas for the nitrification process to contact a high-temperature catalyst.

Furthermore, in the first aspect and second aspect of the present invention, the respective processes can be performed in individual chambers.

In accordance with a third aspect of the present invention, there is provided an apparatus for manufacturing a semiconductor device including: a purification mechanism for purifying, in a vacuum, a surface of a copper-containing metal film, which is exposed on a surface of a semiconductor substrate, by using radicals or by using a thermo-chemical method; a Si infiltration mechanism for infiltrating, in the vacuum, Si into the surface of the copper-containing metal film; and a nitrification mechanism for nitrifying, in the vacuum, a Si-infiltrated portion of the copper-containing metal film by radicals, wherein the purification process, the Si infiltration process and the nitrification process are successively performed without breaking the vacuum.

In accordance with a fourth aspect of the present invention, there is provided an apparatus for manufacturing a semiconductor device including: a purification mechanism for purifying, in a vacuum, a surface of a copper-containing metal film, which is exposed on a surface of a semiconductor substrate, by using radicals or by using a thermo-chemical method; a Si infiltration mechanism for infiltrating, in the vacuum, Si into the surface of the copper-containing metal film; a nitrification mechanism for nitrifying, in the vacuum, a Si-infiltrated portion of the copper-containing metal film by radicals; and a dielectric film formation mechanism for forming, in the vacuum, a dielectric film on a nitride film formed by the nitrification process, wherein the purification process, the Si infiltration process, the nitrification process and the dielectric film formation process are successively performed without breaking the vacuum.

In the third aspect and fourth aspect of the present invention, each of the purification mechanism for performing the purification by the radicals and the nitrification mechanism for performing the nitrification by the radicals may include: a microwave generation unit for generating a microwave; a planar antenna provided with a number of slots; and a microwave transmission mechanism for transmitting the microwave generated from the microwave generation unit to the planar antenna, wherein each the purification mechanism and the nitrification mechanism generate the radicals by converting a processing gas into a plasma by means of the microwave provided from the planar antenna, or may include: a catalyst heated to a high temperature and to be in contact with a processing gas, and generates the radicals when the processing gas contacts the catalyst. Further, the purification mechanism for performing the purification by the thermo-chemical method may include: a heating mechanism for heating a semiconductor substrate; and a reducing gas supply mechanism for supplying a reducing gas to the surface of the copper-containing metal film.

Moreover, in the third aspect and fourth aspect of the present invention, the apparatus can further include a single chamber in which the processes by the respective mechanisms are performed. Further, in the fourth aspect of the present invention, the apparatus can further include a first chamber incorporating therein the purification mechanism, the Si infiltration mechanism and the nitrification mechanism; a second chamber incorporating therein the dielectric film formation mechanism; and a transfer mechanism for transferring the semiconductor substrate between the first chamber and the second chamber without breaking the vacuum. At this time, each of the purification mechanism and the nitrification mechanism may include: a microwave generation unit for generating a microwave; a planar antenna provided with a number of slots; and a microwave transmission mechanism for transmitting the microwave generated from the microwave generation unit to the planar antenna, wherein the radicals are generated by converting a processing gas into a plasma by means of inducing the microwave provided from the planar antenna into the single chamber or into the first chamber, or may include: a catalyst provided in the single chamber or in the first chamber, and the catalyst is heated to a high temperature and is to be in contact with a processing gas, and the radicals are generated in the single chamber or in the first chamber when the processing gas contacts the catalyst.

In the third aspect of the present invention, the apparatus can further include: a first chamber incorporating therein the purification mechanism and the Si infiltration mechanism; a second chamber incorporating therein the nitrification mechanism; and a transfer mechanism for transferring the semiconductor substrate between the first chamber and the second chamber without breaking the vacuum. Further, in the fourth aspect of the present invention, the apparatus can further include: a first chamber incorporating therein the purification mechanism and the Si infiltration mechanism; a second chamber incorporating therein the nitrification mechanism and the dielectric film formation mechanism; and a transfer mechanism for transferring the semiconductor substrate between the first chamber and the second chamber without breaking the vacuum.

Furthermore, in the third aspect and fourth aspect of the present invention, the apparatus can further include: a plurality of chambers incorporating therein the individual mechanisms, respectively; and a transfer mechanism for transferring the semiconductor substrate between the chambers.

In accordance with a fifth aspect of the present invention, there is provided a computer-readable storage medium for storing therein a computer-executable control program for controlling a processing apparatus, wherein, when executed, the control program controls the processing apparatus to perform the semiconductor device manufacturing method disclosed in the first or second aspect.

In accordance with the present disclosure described above, since the purification of the surface of the copper-containing metal film is performed by radicals or by thermo-chemical method and the nitrification of the Si-infiltrated portion is performed by radicals, damage by ions in the plasma can be suppressed. Further, since the purification process, the Si infiltration process and the nitrification process are successively performed without breaking the vacuum, problems due to moisture adsorption onto an interlayer insulating film can be prevented.

### BRIEF DESCRIPTION OF THE DRAWINGS

The above and other features of the present invention will become apparent from the following description of embodiments given in conjunction with the accompanying drawings, in which:

FIG. 1 provides a flowchart to describe a process sequence of a semiconductor device manufacturing method in accordance with an embodiment of the present invention;

FIGS. 2A to 2D set forth cross sectional views to describe the process sequence of the semiconductor device manufacturing method in accordance with the embodiment of the present invention;

FIGS. 3A to 3C present schematic explanatory diagrams to describe a process of forming a CuSiN film in accordance with the embodiment of the present invention;

FIG. 4 is a schematic cross sectional view showing a RLSA (Radial Line Slot Antenna) microwave plasma processing apparatus for performing a semiconductor device manufacturing method in accordance with a first embodiment of the present invention;

FIG. 5 depicts a cross sectional view showing a catalyst processing apparatus for performing a semiconductor device manufacturing method in accordance with a second embodiment of the present invention;

FIG. 6 offers a plan view of a multi-chamber type processing apparatus for performing a semiconductor device manufacturing method in accordance with a third embodiment of the present invention;

FIG. 7 illustrates a cross sectional view of a processing unit for performing a dielectric film formation process, which is applicable to the processing apparatus of FIG. 6; and

FIG. 8 illustrates a cross sectional view showing a processing unit for performing a purification process by a thermo-chemical method and a Si infiltration process, which is applicable to the processing apparatus of FIG. 6.

### DETAILED DESCRIPTION OF THE INVENTION

Hereinafter, embodiments of the present invention will be described in detail with reference to the accompanying drawings.

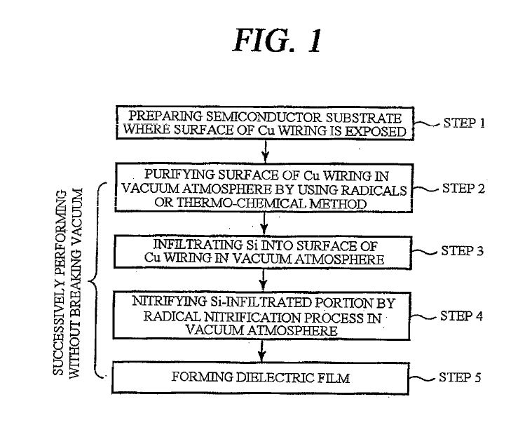

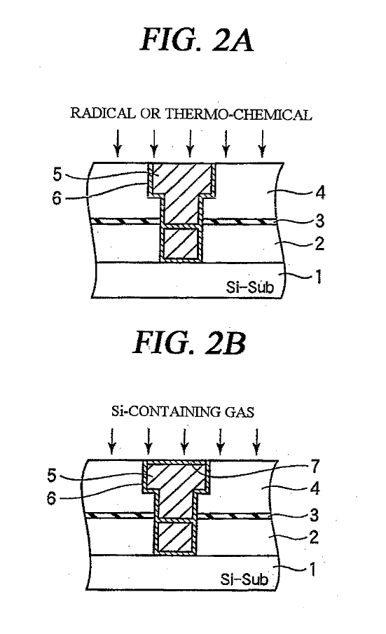

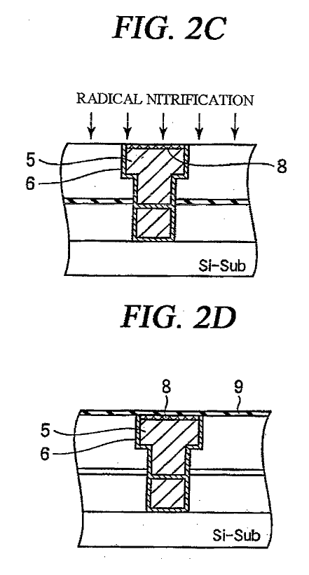

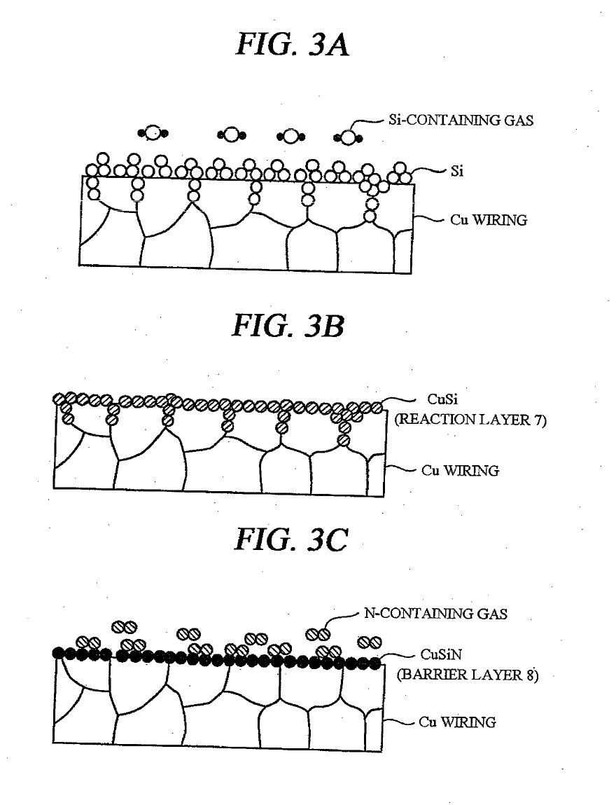

FIG. 1 is a flowchart for describing a process sequence of a semiconductor device manufacturing method in accordance with an embodiment of the present invention, and FIGS. 2A to 2D set forth cross sectional views to describe the process sequence. FIGS. 3A to 3C provide schematic explanatory diagrams to describe a process of forming a CuSiN film in accordance with the embodiment of the present invention.

First, a semiconductor substrate is prepared (Step 1) wherein the semiconductor substrate includes, on a Si base 1, a first interlayer insulating film 2, a dielectric film 3 serving as a Cu diffusion barrier and a second interlayer insulating film 4. A Cu wiring 5 is buried in the first and second interlayer insulating films 2 and 4 while its surface is exposed, and a barrier metal layer 6 is formed on a sidewall of the Cu wiring 5 and on bottoms of portions of the Cu wiring 5 which correspond to the first and second interlayer insulating films 2 and 4. Low-k films are typically used as the interlayer insulating films 2 and 4. Further, though the wiring layers are actually made up of about ten laminated layers, it is shown to have only two layers herein for the simplicity of explanation.

Subsequently, an exposed surface of the Cu wiring 5 is purified in a vacuum atmosphere by using radicals or by using a thermo-chemical method, so that a native oxide film or the like formed on the surface of the Cu wiring 5 is removed (Step 2, see FIG. 2A). By using the radicals or the thermo-chemical method, the purification process can be performed while causing less damage on the second interlayer insulating film 4, in comparison with a conventional plasma process mainly implemented by ions.

When the purification process is performed by the radicals, at least one of a H₂ gas, a N₂ gas, an Ar gas, and a NH₃ gas may be used as a purifying gas. The radicals can be generated by forming a microwave plasma having a low electron temperature and a high density (RLSA microwave plasma) by means of introducing a microwave into a chamber by using a planar antenna having a number of slots, for example, a RLSA (Radial Line Slot Antenna). Alternatively, the radicals can be generated in a catalytic reaction by allowing the processing gas to contact with a heated refractory catalyst.

The purification process by the thermo-chemical method can be implemented by a reduction process which supplies a reducing gas such as hydrogen, organic acid, or the like into a chamber while the semiconductor substrate is being heated in the chamber. As the organic acid, carboxylic acid such as formic acid, acetic acid, butyric acid or the like can be used, and, preferably, carboxylic acid anhydride such as acetic acid anhydride may be utilized.

After the purification process, a process of infiltrating Si into the surface of the Cu wiring 5 is performed without breaking the vacuum atmosphere (Step 3, see FIG. 2B). This process is performed by supplying a Si-containing gas such as a SiH₄ gas, a Si₂H₆ gas, a SiH₂Cl₂ gas, a Si(CH₃)₄ gas, a SiH(CH₃)₃ gas, a SiH₂(CH₃)₂ gas, a SiH₃(CH₃) gas or the like to the semiconductor substrate. As shown in FIG. 3A, Si is diffused and infiltrated into a region including grain boundaries of the surface of the Cu wiring 5, whereby a thin reaction layer 7 is formed by a reaction between Si and Cu as illustrated in FIGS. 2B and 3B. At this time, a substrate temperature is set to be, for example, about 100 to 400° C.

After the Si infiltration process, nitrification of the Si-infiltrated portion is carried out by a radical nitrification process without breaking the vacuum atmosphere (Step 4). As a result, the reaction layer 7 on the surface of the Cu wiring 5 is nitrified as shown in FIG. 2C, so that a semiconductor device having thereon a barrier layer 8 formed of CuSiN is obtained. This radical nitrification process may inflict less damage on the second interlayer insulating film 4, in comparison with a conventional nitrification by a plasma process mainly implemented by ions. Further, since the Si diffused into the region including the grain boundaries of the surface of the Cu wiring 5 is concentrated in an area closer to the surface of the Cu wiring 5 and forms the CuSiN as shown in FIG. 3C, the barrier film 8 can be made thin.

For this radical nitrification process, an N-containing gas is used as a processing gas, and the N-containing gas may be a N₂ gas, a gaseous mixture of a N₂ gas and an Ar gas, a gaseous mixture of a N₂ gas and a H₂ gas, NH₃ gas, or the like. As in the purification process of Step 2, radicals can be generated by forming a microwave plasma having a low electron temperature and a high density by means of introducing a microwave into a chamber by using a planar antenna having a number of slots, for example, a RLSA. Alternatively, the radicals can be generated in a catalytic reaction by means of allowing the processing gas to contact with a heated refractory catalyst.

After forming the barrier layer 8 by the nitrification process, a dielectric film 9 to be used as an etching stopper or a diffusion barrier film is formed, if necessary. SiN, SiCN, SiC, or the like can be used as the dielectric film 9. Here, the dielectric film 9 need not have a barrier function because there exists the barrier layer 8. Even if the barrier function is required, the dielectric film 9 only needs to supplement the barrier layer 8. Thus, the film thickness of the dielectric film 9 can remain thin, so that an undesired increase of its dielectric constant can be avoided. The formation of the dielectric film 9 is performed after the completion of the nitrification process without breaking the vacuum atmosphere. Here, the film formation may be carried out according to a typical method: for example, CVD (Chemical Vapor Deposition), PVD (Physical Vapor Deposition) or the like can be appropriately employed.

As described, by performing the purification process by the radicals or by the thermo-chemical method and by performing the nitrification process by the radical nitrification method, it is possible to reduce the damage upon the second interlayer insulating film 4. Moreover, by performing the purification process, the Si infiltration process, the nitrification process and the optional dielectric film formation process successively without breaking the vacuum atmosphere, the low-k film constituting the second interlayer insulating film 4 can be prevented from adsorbing moisture. As a result, an increase of a barrier property of the second interlayer insulating film 4 against the Cu wiring, an increase of the dielectric constant of the interlayer insulating film 4 and an increase of leakage current therein can be prevented, and a reduction of adhesiveness between the second interlayer insulating film 4 and an upper interlayer insulating film formed thereon can be prevented.

Now, specific embodiments of the present invention will be explained.

### First Embodiment

The first embodiment is described for the case of performing a purification process, a Si infiltration process, a nitrification process and an optional dielectric film formation process all by using a RLSA microwave plasma processing apparatus.

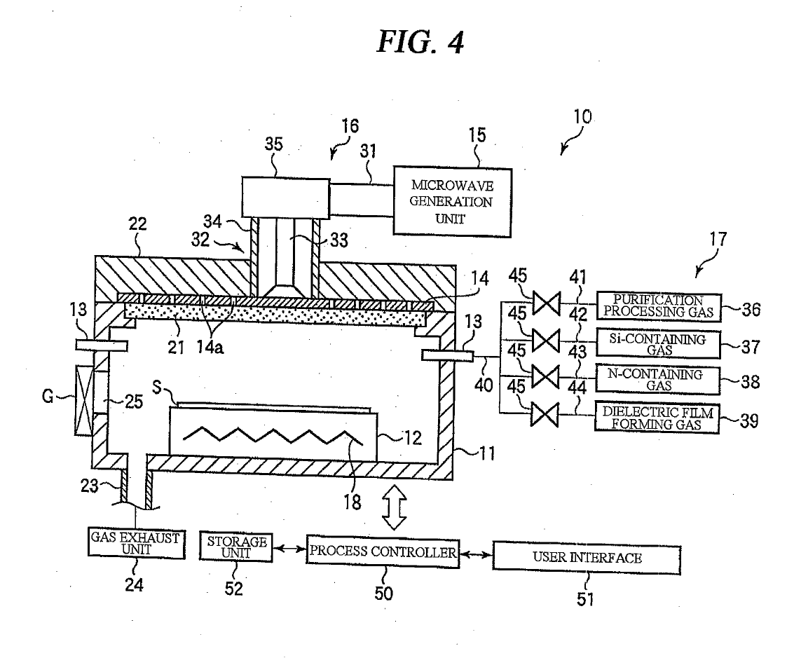

FIG. 4 is a schematic cross sectional view showing a RLSA microwave plasma processing apparatus for performing a semiconductor device manufacturing method in accordance with the first embodiment of the present invention. As shown in FIG. 4, the RLSA microwave plasma processing apparatus 10 includes a substantially cylindrical chamber 11 capable of accommodating a semiconductor substrate therein and maintaining a vacuum therein; a susceptor 12 disposed in a bottom portion of the chamber 11, for mounting the semiconductor substrate thereon; a ring-shaped gas inlet unit 13 provided in a sidewall of the chamber 11, for introducing a processing gas into the chamber 11; a planar antenna 14 disposed to face a top opening of the chamber 11 and provided with a number of microwave transmission holes 14a; a microwave generation unit 15 for generating a microwave; a microwave transmission mechanism 16 for inducing the microwave from the microwave generation unit 15 to the planar antenna 14; and a processing gas supply unit 17 for supplying a processing gas into the gas inlet unit 13.

Installed under the planar antenna 14 is a microwave transmission plate 21 made of a dielectric material, and a shield member 22 is provided on the planar antenna 14. The microwave transmission mechanism 16 includes a horizontally extending waveguide 31 for inducing the microwave from the microwave generation unit 15; a coaxial waveguide 32 having an internal conductor 33 and an external conductor 34, both extending upward from the planar antenna 34; and a mode transducer 35 disposed between the horizontally extending waveguide 31 and the coaxial waveguide 32.

A gas exhaust pipe 23 is connected to a bottom portion of the chamber 11, and connected to the gas exhaust pipe 23 is a gas exhaust unit 24 including a valve, a vacuum pump, or the like for evacuating the chamber 11 to vacuum. Further, provided in a sidewall of the chamber 11 is a loading/unloading port 25 through which the semiconductor substrate S is loaded into or unloaded from the chamber 11. The loading/unloading port 25 can be opened or closed by a gate valve G. The susceptor 12 has a heater 18 embedded therein.

The processing gas supply unit 17 includes a purifying gas supply source 36 for supplying such a purifying gas as enumerated above to be used in the purification process; a Si-containing gas supply source 37 for supplying a Si-containing gas to be used in the Si infiltration process; a N-containing gas supply source 38 for supplying a N-containing gas to be used in the nitrification process; and a dielectric film forming gas supply source 39 for supplying a dielectric film forming gas to be used in the dielectric film formation process. These purifying gas supply source 36, the Si-containing gas supply source 37, the N-containing gas supply source 38 and the dielectric film forming gas supply source 39 are connected to gas supply lines 41 to 44, respectively. The lines 41 to 44 join a common gas supply line 40 and are thereby connected to the gas inlet unit 13. Further, an opening/closing valve 45 and a flow rate controller such as a mass flow controller (not shown) are installed on each of the gas supply lines 41 to 44.

The RLSA microwave plasma processing apparatus 10 includes a process controller 50 having a microprocessor (computer) for controlling individual constituent components of the apparatus 10. Each component of the apparatus 10 is connected to and controlled by the process controller 50. Further, connected to the process controller 50 is a user interface 51 including a keyboard for an operator to input a command or the like to operate the RLSA plasma processing apparatus 10, a display for visualizing and showing an operational status of the plasma processing apparatus 10, and so forth.

Moreover, also connected to the process controller 50 is a storage unit 52 which stores therein control programs to be used in realizing various processes performed by the RLSA microwave plasma processing apparatus 10 under the control of the process controller 50, and programs, i.e., recipes, to be used in operating each component of the RLSA microwave plasma processing apparatus 10 to carry out a desired process according to processing conditions. The recipes are stored in a storage medium inside the storage unit 52. The storage medium may be a hard disk or a semiconductor memory or may be a portable device such as a CDROM, a DVD, a flash memory, or the like. Alternatively, the recipes can be transmitted from another apparatus via, for example, a dedicated line.

When a command is received from the user interface 51, a necessary recipe is retrieved from the storage unit 52 and is executed by the process controller 50, whereby a desired process is performed in the RLSA microwave plasma processing apparatus 10 under the control of the process controller 50.

Now, the manufacturing method in accordance with the first embodiment of the present invention, which is performed by the RLSA microwave plasma processing apparatus 10 having the above-described configuration, will be explained.

First, a semiconductor substrate S is loaded into the chamber 11 and is mounted on the susceptor 12. Then, a purification process of a surface of a Cu wiring exposed on the surface of the semiconductor substrate S is performed.

Specifically, while evacuating the chamber 11 to vacuum by the gas exhaust unit 24, a purifying gas such as a H₂ gas, a N₂ gas, an Ar gas, a NH₃ gas or the like is introduced from the gas supply source 17 into the chamber 11 via the gas inlet unit 13. Then, while the inside of the chamber 11 is kept at a specific pressure degree, a microwave generated by the microwave generation unit 15 is allowed to propagate to the planar antenna 14 in a specific mode via the microwave transmission mechanism 16 to be uniformly provided into the chamber 11 through the microwave transmission holes 14a of the planar antenna 14 and the microwave transmission plate 21. By the microwave thus provided, the purifying gas is converted into a plasma, and by the plasma, a purification process mainly implemented by radicals is carried out, whereby a native oxide film or the like on the surface of the Cu wiring is removed. During this purification process, the internal pressure of the chamber 11 is determined within a pressure range from, for example, about 0.13 to 1333 Pa (1 mTorr to 10 Torr), and a substrate temperature is set to be, for example, about 100 to 400° C.

Since the above-described plasma process of the RLSA microwave type forms a high-density plasma mainly comprised of radicals at a low electron temperature, high-speed processing is possible, hardly inflicting damage on an interlayer insulating film.

After the completion of the purification process, while continuing the evacuation of the chamber 11, a purge gas, for example, an Ar gas, is introduced from a purge gas supply source (not shown) into the chamber 11, whereby a residual gas in the chamber 11 is purged.

Subsequently, without breaking the vacuum in the chamber 11, the gas from the gas supply unit 17 is changed to a Si-containing gas such as a SiH₄ gas, a Si₂H₆ gas, a SiH₂Cl₂ gas, a Si(CH₃)₄ gas, a SiH(CH₃)₃ gas, a SiH₂(CH₃)₂ gas, a SiH₃(CH₃) gas or the like as mentioned above, so that a Si infiltration process is performed. Though it is not particularly necessary to generate a plasma during the Si infiltration process, it may be possible to facilitate decomposition of the Si-containing gas by generating a microwave plasma depending on the gas employed. During the Si infiltration process, the internal pressure of the chamber 11 is determined within a pressure range from, for example, about 1.3 to 1333 Pa (10 mTorr to 10 Torr), and the substrate temperature is set to be, for example, about 100 to 400° C. As a result of the Si infiltration process, CuSi is formed on the surface of the Cu wiring, as described above.

After the completion of the Si infiltration process, while continuing the evacuation of the chamber 11, a purse gas, for example, an Ar gas is supplied into the chamber 11 from the purge gas supply source (not shown)., whereby a residual gas in the chamber 11 is purged. Alternatively, it is also possible to evacuate the chamber 11 until the chamber 11 is substantially vacuumized.

Subsequently, without breaking the vacuum in the chamber 11, the gas from the gas supply unit 17 is changed to a N-containing gas such as a N₂ gas, a gaseous mixture of a N₂ gas and an Ar gas, a gaseous mixture of a N₂ gas and a H₂ gas, a NH₃ gas, or the like as mentioned above, and a microwave generated from the microwave generating unit 15 is propagated to the planar antenna 14 in a specific mode via the microwave transmission mechanism 16 to be uniformly provided into the chamber 11 through the microwave transmission holes 14a of the planar antenna 14 and the microwave transmission plate 21. By the microwave thus provided, the N-containing gas is converted into a plasma, and a radical nitrification process mainly implemented by radicals is carried out, so that the CuSi formed on the surface of the Cu wiring is nitrified to form CuSiN. During this nitrification process, the internal pressure of the chamber 11 is determined within a pressure range from, for example, about 1.3 to 1333 Pa (10 mTorr to 10 Torr), and the substrate temperature is set to be, for example, about 100 to 400° C.

Since a plasma process of a RLSA microwave type is employed in the nitrification process as in the purification process, a high-density plasma mainly comprised of radicals is generated at a low electron temperature. Thus, high-speed processing can be carried out, hardly inflicting damage on the interlayer insulating film.

Though a semiconductor device having a barrier film made of CuSiN formed on the surface of the Cu wiring is obtained by the nitrification process, it is possible to additionally form a dielectric film, as mentioned above, on the barrier film to use it as an etching stopper or a diffusion barrier film, if necessary. The formation of the dielectric film involves the steps of changing the gas from the gas supply unit 17 to a dielectric film forming gas without breaking the vacuum in the chamber 11 and then depositing a dielectric film made of SiN, SiCN, SiC or the like on the barrier film by CVD. For the dielectric film formation process, a gas such as Si(CH₃)₄, SiH(CH₃)₃, SiH₂(CH₃)2, SiH₃(CH₃), dimethyl phenyl silane or the like is used as the dielectric film forming gas, and the substrate temperature is preferably set to be, for example, about 100 to 400° C.

In the first embodiment as described above, since the purification process, the Si in-filtration process, the nitrification process and the dielectric film formation process are all performed in a single chamber which is kept in vacuum, moisture adsorption to the interlayer insulating film made of the low-k film can be prevented almost perfectly. Furthermore, since the purification process and the nitrification process are carried out by the radical processes with the RLSA microwave plasma, damage inflicted on the interlayer insulating film can be reduced greatly, in comparison with conventional plasma processes mainly implemented by ions.

### Second Embodiment

The second embodiment is described for the case of performing a purification process, a Si infiltration process, a nitrification process and an optional dielectric film formation process all by using a catalyst processing apparatus.

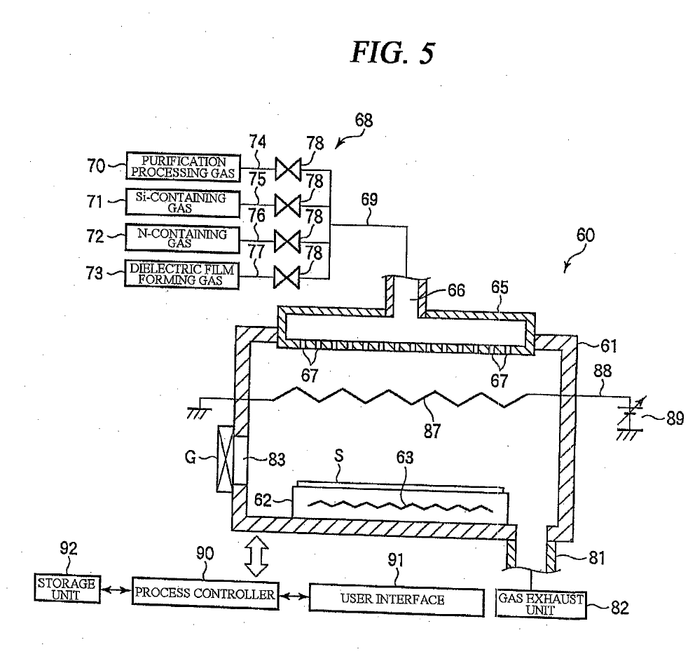

Referring to FIG. 5, there is provided a schematic cross sectional view showing a catalyst processing apparatus 60 for performing a semiconductor device manufacturing method in accordance with the second embodiment of the present invention. As shown in FIG. 5, the catalyst processing apparatus 60 includes a substantially cylindrical chamber 61 capable of accommodating a semiconductor substrate and maintaining a vacuum therein. A susceptor 62 is disposed in a bottom portion of the chamber 61, and a heater 63 for heating the semiconductor substrate S is embedded in the susceptor 62.

Provided at a top portion of the chamber 61 to face the suscpetor 62 is a hollow disk-shaped shower head 65 serving to introduce a processing gas into the chamber 61. The shower head 65 has a gas inlet port 66 at the center of an upper surface thereof and is provided with a number of gas discharge holes 67 in a lower surface thereof.

A processing gas supply unit 68 for supplying a processing gas is connected to the shower head 65. The processing gas supply unit 68 includes a purifying gas supply source 70 for supplying such a purifying gas as mentioned above to be used in the purification process; a Si-containing gas supply source 71 for supplying a Si-containing gas to be used in the Si infiltration process; a N-containing gas supply source 72 for supplying a N-containing gas to be used in the nitrification process; and a dielectric film forming gas supply source 73 for supplying a dielectric film forming gas to be used in the dielectric film formation process. These purifying gas supply source 70, the Si-containing gas supply source 71, the N-containing gas supply source 72 and the dielectric film forming gas supply source 73 are connected to gas supply lines 74 to 77, respectively. The gas supply lines 74 to 77 join a common gas supply line 69 and are thereby connected to the gas inlet port 66 of the shower head 65. Further, an opening/closing valve 78 and a flow rate controller (not shown) such as a gas flow controller are installed on each of the gas supply lines 74 to 77.

A gas exhaust pipe 81 is connected to a bottom portion of the chamber 61, and a gas exhaust unit 82 including a valve, a vacuum pump or the like for exhausting the chamber 61 is coupled to the gas exhaust pipe 81. Further, provided in a sidewall of the chamber 61 is a loading/unloading port 83 through which the semiconductor substrate S is loaded into or unloaded from the chamber 61. The loading/unloading port 83 can be opened or closed by a gate valve G.

A catalyst wire 87 made of a refractory conductive material, for example, tungsten, is disposed between the susceptor 62 and the shower head 65 inside the chamber 61. A power supply line 88 connected with a variable DC power supply 89 is coupled to one end of the catalyst wire 87. As a power is supplied from the variable DC power supply 89 to the catalyst wire 87, the catalyst wire 87 is heated up to a specific temperature higher than or equal to about 1400° C. Meanwhile, the other end of the catalyst wire 87 is grounded. Further, the material for the catalyst wire 87 is not limited to the tungsten, and any refractory metal capable of being heated to a high temperature no smaller than 1400° C., for example, tantalum, molybdenum, vanadium, platinum, thorium or the like can be employed. Moreover, these refractory metals such as tungsten may not be single element metals.

When the catalyst wire 87 is heated up to the preset temperature, a processing gas is introduced into the chamber 61, and as the processing gas contacts the catalyst wire 87, the processing gas is excited by a catalytic cracking reaction, so that radicals are generated. By these radicals, a purification process or a nitrification process is carried out.

The catalyst processing apparatus 60 includes a process controller 90 having a microprocessor (computer) for controlling individual constituent component of the apparatus 60. Each component of the catalyst processing apparatus 60 is connected to and controlled by the process controller 90. Connected to the process controller 90 are a user interface 91 and a storage unit 92. The process controller 90, the user interface 91 and the storage unit 92 have the same configurations as those of the process controller 50, the user interface 51 and the storage unit 52 in the first embodiment.

Below, a semiconductor device manufacturing method in accordance with the second embodiment, which is performed by the catalyst processing apparatus 60 having the above-described configuration, will be explained.

First, a semiconductor wafer S is loaded into the chamber 61 and mounted on the susceptor 62, and a purification process of a surface of a Cu wiring exposed on the surface of the semiconductor substrate S is performed.

Specifically, while the chamber 61 is evacuated by the gas exhaust unit 82, a purifying gas such as a H₂ gas, a N₂ gas, an Ar gas, a NH₃ gas as described above is supplied into the chamber 61 from the processing gas supply unit 68 via the shower head 65. Then, while keeping the inside of the chamber 61 at a certain pressure level, the semiconductor wafer S on the susceptor 62 is heated to a preset temperature by the heater 63.

Meanwhile, the catalyst wire 87 is powered by the variable DC power supply 89 to be heated and controlled at a preset temperature preferably ranging from about 1400 to 2000° C. If the above-cited purifying gas is introduced while the catalyst wire 87 is kept at such high temperature level, the purifying gas contacts the catalyst wire 87 and is excited by a catalytic cracking reaction, whereby radicals are generated. By allowing the thus generated radicals to contact the surface of the Cu wiring of the semiconductor substrate S, a native oxide film or the like on the surface of the Cu wiring is removed by a catalytic cracking reaction. This purification process can be carried out by releasing the purifying gas while regulating the temperature of the catalyst wire and the temperature of the substrate at, for example, about 1000 to 2000° C. and about 100 to 400° C., respectively.

The catalyst processing apparatus described above is capable of generating high-density radicals with the very simple configuration and is also capable of realizing a low-price processing apparatus. Moreover, high-speed processing is possible by the radicals, hardly inflicting damage on an interlayer insulating film.

After the completion of the purification process, while continuing the evacuation of the chamber 61, a purge gas, for example, an Ar gas is supplied from a purge gas supply source (not shown) into the chamber 61, whereby a residual gas in the chamber 61 is purged.

Subsequently, without breaking the vacuum in the chamber 61, the gas from the processing gas supply unit 68 is changed to a Si-containing gas such as a SiH₄ gas, a Si₂H₆ gas, a SiH₂Cl₂ gas, a Si(CH₃) ₄ gas, a SiH(CH₃)₃ gas, a SiH₂(CH₃)₂ gas, a SiH₃(CH₃) gas or the like as mentioned above, and a Si infiltration process is performed by setting the temperature of the susceptor 62 at a certain temperature level. Though is it not particularly necessary to generate a plasma during the Si infiltration process, it may be possible to generate radicals by heating the catalyst wire 87, depending on the gas employed. During the Si infiltration process, the internal pressure of the chamber 61 is determined within a pressure range from, for example, about 1.3 to 1333 Pa (10 mTorr to 10 Torr), and the substrate temperature is set to be, for example, about 100 to 400° C. As a result of the Si infiltration process, CuSi is formed on the surface of the Cu wiring, as described above.

Upon the completion of the Si infiltration process, while continuing the evacuation of the chamber 61, a purse gas, for example, an Ar gas is supplied into the chamber 61 from a purge gas supply source (not shown), whereby a residual gas in the chamber 61 is purged. Alternatively, it is also possible to evacuate the chamber 61 until the chamber 61 is substantially vacuumized.

Subsequently, without breaking the vacuum in the chamber 61, the gas from the gas supply unit 68 is changed to a N-containing gas such as a N₂ gas, a gaseous mixture of a N₂ gas and an Ar gas, a gaseous mixture of a N₂ gas and a H₂ gas, a NH₃ gas, or the like as mentioned above, and the semiconductor substrate S on the susceptor 62 is heated by the heater 63 to a preset temperature, while the inside of the chamber 61 is kept at a specific pressure degree. Meanwhile, the catalyst wire 87 is powered by the variable DC power supply 89 to be heated and controlled at a specific temperature preferably ranging from about 1400 to 2000° C. While the catalyst wire 87 is kept at such high temperature level, the N-containing gas is introduced into the chamber 61 and is excited by a catalytic cracking reaction as a result of the contact of the N-containing gas with the catalyst wire 87, whereby N-containing radicals are generated. By the N-containing radicals thus generated, a radical nitrification process is performed to nitrify the CuSi formed on the Cu wiring surface, so that CuSiN is formed. This nitrification process can be performed by releasing the N-containing gas while setting the temperature of the catalyst wire 87 and the temperature of the substrate S to be, for example, about 1000 to 2000° C. and about 100 to 400° C., respectively.

In the above nitrification process, high-density radicals can be generated by the apparatus having the very simple configuration, so that a low-price processing apparatus can be realized as in the purification process. Moreover, high-speed processing is possible by the radicals, hardly inflicting damage on an interlayer insulating film.

Though a semiconductor device having a barrier film made of the CuSiN formed on the surface of the Cu wiring is obtained by the above-described nitrification process, it is possible to additionally form a dielectric film, as mentioned above, on the barrier film to use it as an etching stopper or a diffusion barrier film, if necessary. The formation of the dielectric film involves the steps of changing the gas from the gas supply unit 68 to a dielectric film forming gas without breaking the vacuum in the chamber 61 and then depositing a dielectric film made of SiN, SiCN, SiC or the like on the barrier film by CVD. Here, though it is not particularly necessary to heat the catalyst wire 87, it may be possible to generate radicals by heating the catalyst wire 87 depending on the gas employed.

In the second embodiment described above, since the purification process, the Si infiltration process, the nitrification process and the dielectric film formation process are all performed in a single chamber which is kept in vacuum, moisture adsorption to the interlayer insulating film made of the low-k film can be prevented almost perfectly. Furthermore, since the purification process and the nitrification process are performed by the radicals generated as a result of the contact of the processing gases with the heated catalyst wire 87, damage inflicted on the interlayer insulating film can be reduced greatly, in comparison with conventional plasma processes mainly implemented by ions.

### Third Embodiment

Though the first and second embodiments have been described for the case of performing the purification process, the Si infiltration process, the nitrification process and the dielectric film formation process in the single chamber, there is a likelihood that a gas supply system may be complicated or a throughput may be reduced due to the execution of gas purges between the processes if all these processes are performed in the same chamber. Thus, to solve these problems, a plurality of processing chambers are provided in the third embodiment, and these processes are performed by using a transfer apparatus capable of transferring a target substrate between the processing chambers without breaking a vacuum therein.

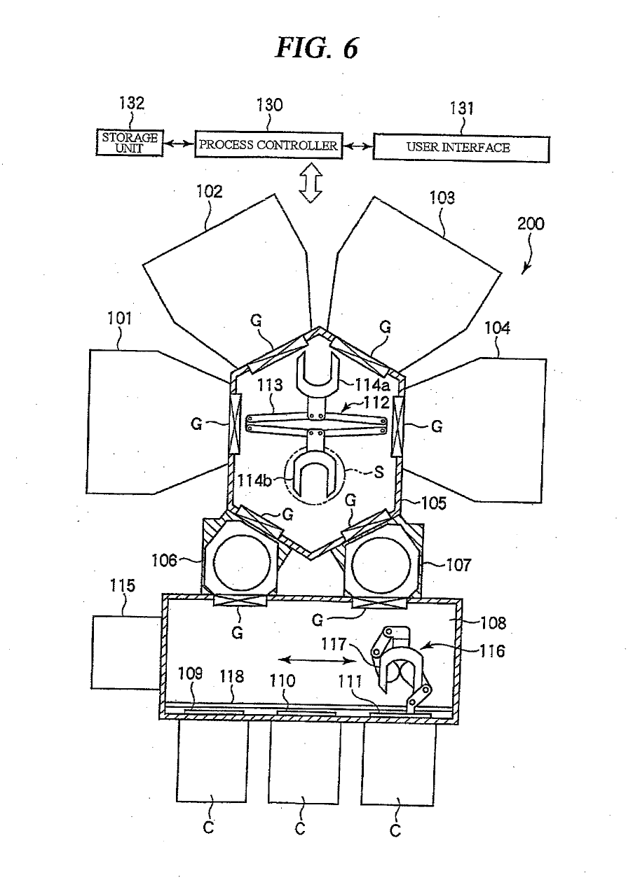

FIG. 6 is a plan view showing a schematic configuration of a multi-chamber type processing apparatus 200 used to perform a semiconductor device manufacturing method in accordance with the third embodiment of the present invention. The processing apparatus 200 includes four processing units 101 to 104 that are provided to correspond to four sides of a transfer chamber 105 having a hexagonal shape, respectively. Further, load lock chambers 106 and 107 are respectively provided on the remaining two sides of the transfer chamber 105. A loading/unloading chamber 108 is provided on the opposite side of the load lock chambers 106 and 107 to the transfer chamber 105. Ports 109 to 111 to which three carriers C for containing wafers S therein are respectively attached are provided on the opposite side of the loading/unloading chamber 108 to the load lock chambers 106 and 107.

The processing units 101 to 104 and the load lock chambers 106 and 107 are connected to the respective sides of the transfer chamber 105 through gate valves G, as shown in the FIG. 6. They are allowed to communicate with the transfer chamber 105 by opening the corresponding gate valves G, and are isolated from the transfer chamber 105 by closing the corresponding gate valves G. Gate valves G are also provided at portions of the load lock chambers 106 and 107 that make connection with the loading/unloading chamber 108. The load lock chambers 106 and 107 communicate with the loading/unloading chamber 108 when the corresponding gate valves G are opened, and are isolated from the loading/unloading chamber 108 when the corresponding gate valves G are closed.

In the transfer chamber 105, there is installed a transfer mechanism 112 which performs loading and unloading of a semiconductor substrate S with respect to the processing units 101 to 104 and the load lock chambers 106 and 107. The wafer transfer mechanism 112 is disposed substantially at the center of the transfer chamber 105, and it includes a rotatable and extendible/retractable unit 113 that can make rotating, extending and retracting motions. At the tip ends of the rotatable and extendible/retractable unit 113, there are provided two blades 114a and 114b for holding the semiconductor substrate S, wherein the two blades 114a and 114b are attached to the rotatable and extendible/retractable unit 113 such that they can be oriented in mutually opposite directions. Moreover, the interior of the transfer chamber 105 is maintained at a specific vacuum level.

Each of the three ports 109 to 111 of the loading/unloading chamber 108 is provided with a shutter (not shown). When the carriers C, either accommodating semiconductor substrates S therein or remaining empty, are directly attached to the ports 109 to 111, and the shutters are then opened so that the carriers C are allowed to communicate with the loading/unloading chamber 108 while preventing an infiltration of exterior air. Furthermore, an alignment chamber 115 is provided at one side of the loading/unloading chamber 108, and alignment of the semiconductor substrates S is performed therein.

Disposed in the loading/unloading chamber 108 is a transfer mechanism 116 which performs loading and unloading of the semiconductor substrate S with respect to the carriers C and the load lock chambers 106 and 107. The transfer mechanism 116 has a multi-joint arm structure and is capable of moving along a rail 118 in an arrangement direction of the carriers C. The transfer mechanism 116 is adapted to transfer the semiconductor substrate S by holding the substrate S with a hand 117 provided at a leading end thereof.

The processing apparatus 200 includes a process controller 130 having a microprocessor (computer) for controlling individual constituent components of the apparatus 200, i.e., the processing units, the transfer system, the gas supply system, and so forth. Each component is connected to and controlled by the process controller 130. Further, a user interface 131 and a storage unit 132 are connected to the process controller 130. The process controller 130, the user interface 131 and the storage unit 132 have the same configurations as those of the process controller 50, the user interface 51 and the storage unit 52 described in the first embodiment.

In the third embodiment, some processes of the purification process, the Si infiltration process, the nitrification process and the dielectric film formation process are performed by one of the processing units 101 to 104, while the rest processes are performed by one or more other processing units.

Specifically, available combinations of the target processes and the processing units are as follows:

(1) the purification process, the Si infiltration process and the nitrification process are performed by one processing unit, while the dielectric film formation process is performed by another processing unit;

(2) the purification process and the Si infiltration process are performed by one processing unit, while the nitrification process and the dielectric film formation process are performed by another processing unit; and

(3) the purification process, the Si infiltration process, the nitrification process and the dielectric film formation process are all performed by different processing units. Further, beside these examples, other combinations may be possible.

In case of the method of combination (1), as the processing unit for performing the purification process, the Si infiltration process and the nitrification process, there can be employed an apparatus having the same configuration as that of the RLSA microwave plasma processing apparatus 10 of the first embodiment excepting that the dielectric film forming gas supply source 39 is omitted or an apparatus having the same configuration as that of the catalyst processing apparatus 60 of the second embodiment excepting that the dielectric film forming gas supply source 73 is omitted. By using such processing unit, the purification process, the Si infiltration process, the nitrification process can be carried out in the above-described sequence.

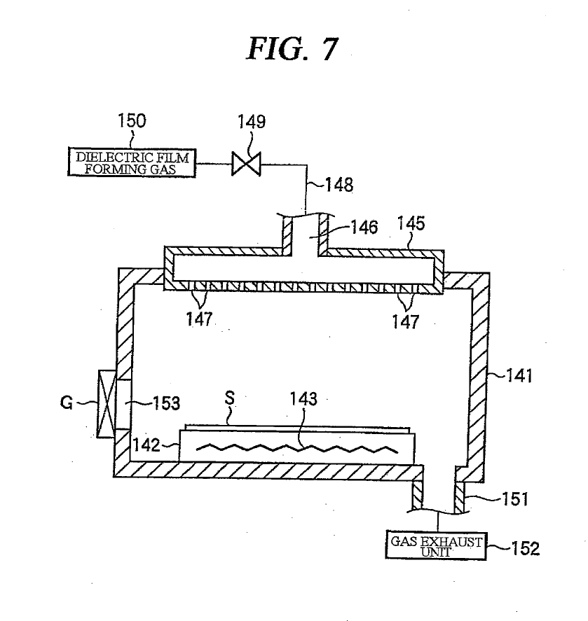

Meanwhile, as the processing unit for performing the dielectric film formation process, a processing unit configured as shown in FIG. 7 can be employed. This processing unit includes a substantially cylindrical chamber 141 capable of accommodating a semiconductor substrate S and maintaining a vacuum therein. A susceptor 142 is disposed in a bottom portion of the chamber 141, and a heater 143 for heating the semiconductor substrate S is embedded in the susceptor 142.

Provided at a top portion of the chamber 141 to face the suscpetor 142 is a hollow disk-shaped shower head 145 serving to introduce a dielectric film forming gas into the chamber 141. The shower head 145 has a gas inlet port 146 at the center of an upper surface thereof and is provided with a number of gas discharge holes 147 in a lower surface thereof.

One end of a gas supply line 148 is connected to the gas inlet port 146 of the shower head 145, and the other end of the gas supply line 148 is connected to a dielectric film forming gas supply source 150. Further, an opening/closing valve 149 and a flow rate controller (not shown) such as a gas flow controller are installed on the gas supply line 148.

A gas exhaust pipe 151 is connected to a bottom portion of the chamber 141, and a gas exhaust unit 152 including a valve, a vacuum pump, or the like for evacuating the chamber 141 is coupled to the gas supply line 151. Further, provided in a sidewall of the chamber 141 is a loading/unloading port 153 through which the semiconductor substrate S is loaded into or unloaded from the chamber 141. The loading/unloading port 153 can be opened or closed by a gate valve G.

In the processing unit configured as described above, a semiconductor substrate S, which has a barrier film made of CuSiN and formed on the surface of a Cu wiring through the nitrification process, is loaded into the chamber 141 and is mounted on the susceptor 142. Then, while evacuating the chamber 141 to vacuum by the gas exhaust unit 152, the dielectric film forming gas is supplied from the dielectric film forming gas supply source 150 into the chamber 141 via the shower head 145. Thereafter, while keeping the inside of the chamber 141 at a specific pressure level, the semiconductor substrate S on the susceptor 142 is heated to a preset temperature by the heater 143. As a result, a dielectric film is formed on the barrier film by CVD. During this dielectric film formation process, the internal pressure of the chamber 141 is determined in the range from, for example, about 1.3 Pa to 1333 Pa (10 mTorr to 10 Torr), and the substrate temperature is set to be, for example, about 100 to 400° C.

In case of the method of combination (2), as the processing unit for performing the purification process and the Si infiltration process, there can be employed an apparatus having the same configuration as that of the RLSA microwave plasma processing apparatus 10 of the first embodiment excepting that the N-containing gas supply source 38 and the dielectric film forming gas supply source 39 are omitted or an apparatus having the same configuration as that of the catalyst processing apparatus 60 of the second embodiment excepting that the N-containing gas supply source 72 and the dielectric film forming gas supply source 73 are omitted. By using such processing unit, the purification process and the Si infiltration process can be performed in the above-described sequence.

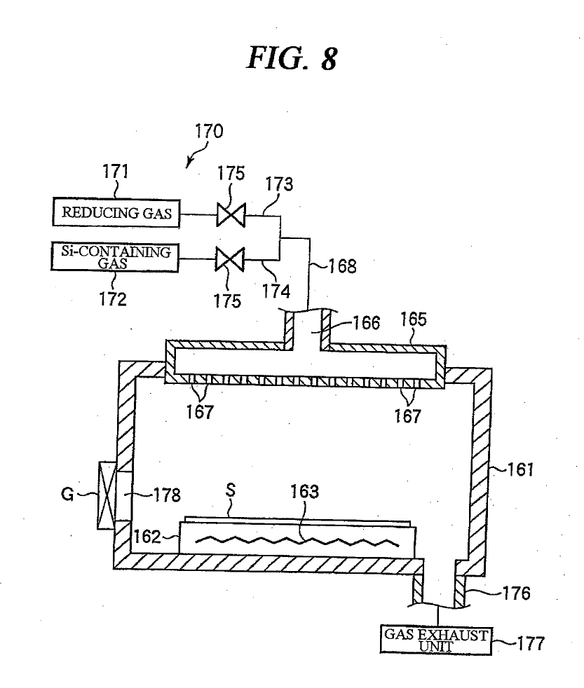

Further, besides these processing apparatuses capable of performing the target processes by radicals, it is also possible to perform the purification process and the Si infiltration process by using a processing unit, as illustrated in FIG. 8, capable of performing the purification process by a thermo-chemical method.

This processing unit includes a substantially cylindrical chamber 161 capable of accommodating a semiconductor substrate S and maintaining a vacuum therein. A susceptor 162 is disposed in a bottom portion of the chamber 161, and a heater 163 for heating the semiconductor substrate S is embedded in the susceptor 162.

Provided at a top portion of the chamber 161 to face the susceptor 162 is a hollow disk-shaped shower head 165 serving to introduce a processing gas into the chamber 161. The shower head 165 is provided with a gas inlet port 166 at the center of an upper surface thereof and is provided with a number of gas discharge holes 167 in a lower surface thereof.

Connected to the shower head 165 is a processing gas supply unit 170 for supplying the processing gas. The processing gas supply unit 170 includes a reducing gas supply source 171 for supplying a reducing gas such as hydrogen, organic acid or the like as described above to be used in the purification process; and a Si-containing gas supply source 172 for supplying a Si-containing gas to be used in the Si infiltration process. The reducing gas supply source 171 and the Si-containing gas supply source 172 are connected to gas supply lines 173 and 174, respectively. The gas supply lines 173 and 174 join a common gas supply line 168 and are thereby connected to the gas inlet port 166 of the shower head 165. Further, an opening/closing valve 175 and a flow rate controller (not shown) such as a gas flow controller are installed on each of the gas supply lines 173 and 174.

A gas exhaust pipe 176 is connected to a bottom portion of the chamber 161, and a gas exhaust unit 177 including a valve, a vacuum pump or the like for evacuating the chamber 161 is connected to the gas exhaust pipe 176. Further, provided in a sidewall of the chamber 161 is a loading/unloading port 178 through which the semiconductor substrate S is loaded into or unloaded from the chamber 161. The loading/unloading port 178 can be opened or closed by a gate valve G.

In the processing unit having the above-described configuration, a semiconductor substrate S is loaded into the chamber 161 and is placed on the susceptor 162. Then, while evacuating the chamber 161 to vacuum by the gas exhaust unit 177, the reducing gas is supplied from the reducing gas supply source 171 of the processing gas supply unit 170 into the chamber 161 via the shower head 165. While the inside of the chamber 161 is kept at a specific pressure level, the semiconductor substrate S on the susceptor 162 is heated to a preset temperature degree by the heater 163. As a result, a native oxide film formed on the surface of the Cu wiring on the semiconductor substrate S is reduced by the reducing gas and is thereby eliminated. During this process, the internal pressure of the chamber 161 is determined within a pressure range from, for example, about 1.3 Pa to 1333 Pa (10 mTorr to 10 Torr) and the substrate temperature is set to be, for example, about 100 to 400° C.

Moreover, a processing apparatus capable of performing a radical nitrification is employed as a processing unit for performing the nitrification process and the dielectric film formation process in the method of combination (2). That is, the nitrification process and the dielectric film formation process can be performed in the above-described sequence by using an apparatus having the same configuration as that of the RLSA microwave plasma processing apparatus 10 of the first embodiment excepting that the purification processing gas supply source 36 and the Si-containing gas supply source 37 are omitted or by using an apparatus having the same configuration as that of the catalyst processing apparatus 60 of the second embodiment excepting that the purifying gas supply source 70 and the Si-containing gas supply source 71 are omitted.

Further, when the individual processes are performed by different processing units in the method of combination (3), the RLSA microwave plasma processing apparatus 10 illustrated in FIG. 4 or the catalyst processing apparatus: 60 shown in FIG. 5 can be used as a processing unit for the purification process. By using these apparatuses, the purification process by radicals can be performed.

Moreover, a processing unit that performs a purification process by a thermo-chemical method using a reducing gas such as hydrogen, organic oxide, or the like, as shown in FIG. 8, can also be used as the processing unit for the purification process.

The Si infiltration process can be performed by a processing unit having the same configuration as that of the processing unit of FIG. 8 excepting that the reducing gas supply source 171 is omitted.

As for the nitrification process, the RLSA microwave plasma processing apparatus 10 shown in FIG. 4 or the catalyst processing apparatus illustrated in FIG. 5 can be used as a processing unit for the nitrification process, and by these apparatuses, a radical nitrification process is conducted.

The dielectric film formation process in this method can also be performed by the apparatus described in FIG. 7.

When performing these processes by the processing apparatus of FIG. 6, one sheet of semiconductor substrates S is first taken out of the carriers C by the transfer mechanism 116 and placed on a mounting table of the load lock chamber 106 or 107. Then, after evacuating the load lock chamber accommodating the semiconductor substrate S to vacuum, the semiconductor substrate S is transferred from that load lock chamber into the transfer chamber 105 which is kept in vacuum and is then loaded into one of the processing units 101 to 104 which is supposed to perform a first process. After the first process in the processing unit is completed, the semiconductor substrate S is unloaded therefrom and is transferred into a next processing unit via the transfer chamber 105.

In this third embodiment, though the series of these processes are performed by the plural processing units in the processing apparatus of FIG. 6, these processing units are all connected to the transfer chamber 105, and the transfer of the semiconductor substrate S between these processing units can be performed without breaking the vacuum by the transfer mechanism 112. Therefore, adsorption of moisture to an interlayer insulating film made of a low-k film can be suppressed sufficiently.

Here, it is to be noted that the present invention is not limited to the above-described embodiments but can be modified in various ways. For example, though the RLSA microwave plasma processing apparatus or the catalyst processing apparatus is used to perform the purification process for the surface of the Cu wiring and the nitrification process after the completion of the Si infiltration process by radicals in the above described embodiments, any other types of processing apparatuses can be employed instead as long as they can carry out the target processes by radicals. Furthermore, the thermo-chemical method mentioned above is just one example, and other different methods can be employed instead. Moreover, as for the apparatus for performing the Si infiltration process or the dielectric film formation process, the ones described in the embodiments are nothing more than examples, and other proper apparatuses can be employed instead.

While the invention has been shown and described with respect to the embodiments, it will be understood by those skilled in the art that various changes and modifications may be made without departing from the scope of the invention as defined in the following claims.

What is claimed is:

1. A method for manufacturing a semiconductor device comprising:
preparing a semiconductor substrate having a copper-containing metal film exposed on a surface thereof;
purifying a surface of the copper-containing metal film by using radicals or by using a thermo-chemical method;
infiltrating Si into the surface of the copper-containing metal film; and
nitrifying a Si-infiltrated portion of the copper-containing metal film by radicals,
wherein the purification process, the Si infiltration process and the nitrification process are successively performed without breaking a vacuum.

2. A method for manufacturing a semiconductor device comprising:
preparing a semiconductor substrate having a copper-containing metal film exposed an a surface thereof;
purifying a surface of the copper-containing metal film by using radicals or by using a thermo-chemical method;
infiltrating Si into the surface of the copper-containing metal film;
nitrifying a Si-infiltrated portion of the copper-containing metal film by radicals; and
forming a dielectric film on a nitride film formed by the nitrification process,
wherein the purification process, the Si infiltration process, the nitrification process and the dielectric film formation process are successively performed without breaking a vacuum.

3. The method of claim 1, wherein the purification process is performed by the radicals of a processing gas containing at least one of a H₂ gas, a N₂ gas, an Ar gas, and a NH₃ gas.

4. The method of claim 3, wherein the purification process is performed by the radicals generated by converting the processing gas into a plasma by means of a microwave provided from a planar antenna having a number of slots.

5. The method of claim 3, wherein the purification process is performed by the radicals generated by allowing the processing gas to contact with a high-temperature catalyst.

6. The method of claim 1, wherein the thermo-chemical method for the purification process is implemented by supplying a reducing gas to the surface of the copper-containing metal film while the semiconductor substrate is being heated.

7. The method of claim 1, wherein the nitrification process is performed by using the radicals of an N-containing gas.

8. The method of claim 7, wherein the nitrification process is performed by the radicals generated by converting the N-containing gas into a plasma by means of a microwave provided from a planar antenna having a number of slots.

9. The method of claim 7, wherein the nitrification process is performed by the radicals generated by allowing the N-containing gas to contact with a high-temperature catalyst.

10. The method of claim 1, wherein the series of the processes are performed in the same chamber.

11. The method of claim 1, wherein the purification process and the Si infiltration process are performed in a first chamber, while the other processes are performed in a second chamber.

12. The method of claim 2, wherein the purification process and the Si infiltration process are performed in a first chamber, while the nitrification process and the dielectric film formation process are performed in a second chamber.

13. The method of claim 2, wherein the purification process, the Si infiltration process and the nitrification process are performed in a first chamber, while the dielectric film formation process is performed in a second chamber.

14. The method of claim 13, wherein the first chamber has a function of generating the radicals by converting a gas for the purification process and a gas for the nitrification process into a plasma by means of a microwave provided from a planar antenna having a number of slots.

15. The method of claim 13, wherein the first chamber has a function of generating the radicals by allowing a gas for the purification process and a gas for the nitrification process to contact a high-temperature catalyst.

16. The method of claim 1, wherein the respective processes are performed in individual chambers.

17. An apparatus for manufacturing a semiconductor device comprising:
a purification mechanism for purifying, in a vacuum, a surface of a copper-containing metal film, which is exposed on a surface of a semiconductor substrate, by using radicals or by using a thermo-chemical method;
a Si infiltration mechanism for infiltrating, in the vacuum, Si into the surface of the copper-containing metal film; and
a nitrification mechanism for nitrifying, in the vacuum, a Si-infiltrated portion of the copper-containing metal film by radicals,
wherein the purification process, the Si infiltration process and the nitrification process are successively performed without breaking the vacuum.

18. An apparatus for manufacturing a semiconductor device comprising:
a purification mechanism for purifying, in a vacuum, a surface of a copper-containing metal film, which is exposed on a surface of a semiconductor substrate, by using radicals or by using a thermo-chemical method;
a Si infiltration mechanism for infiltrating, in the vacuum, Si into the surface of the copper-containing metal film;
a nitrification mechanism for nitrifying, in the vacuum, a Si-infiltrated portion of the copper-containing metal film by radicals; and
a dielectric film formation mechanism for forming, in the vacuum, a dielectric film on a nitride film formed by the nitrification process,
wherein the purification process, the Si infiltration process, the nitrification process and the dielectric film formation process are successively performed without breaking the vacuum.

19. The apparatus of claim 17, wherein each of the purification mechanism for performing the purification by the radicals and the nitrification mechanism for performing the nitrification by the radicals includes:
a microwave generation unit for generating a microwave;
a planar antenna provided with a number of slots; and
a microwave transmission mechanism for transmitting the microwave generated from the microwave generation unit to the planar antenna,
wherein each the purification mechanism and the nitrification mechanism generate the radicals by converting a processing gas into a plasma by means of the microwave provided from the planar antenna.

20. The apparatus of claim 17, wherein each of the purification mechanism for performing the purification by the radicals and the nitrification mechanism for performing the nitrification by the radicals includes a catalyst heated to a high temperature and to be in contact with a processing gas, and generates the radicals when the processing gas contacts the catalyst.

21. The apparatus of claim 17, wherein the purification mechanism for performing the purification by the thermo-chemical method includes:
a heating mechanism for heating a semiconductor substrate; and
a reducing gas supply mechanism for supplying a reducing gas to the surface of the copper-containing metal film.

22. The apparatus of claim 17, further comprising a single chamber in which the processes by the respective mechanisms are performed.

23. The apparatus of claim 18, further comprising:
a first chamber incorporating therein the purification mechanism, the Si infiltration mechanism and the nitrification mechanism;
a second chamber incorporating therein the dielectric film formation mechanism; and
a transfer mechanism for transferring the semiconductor substrate between the first chamber and the second chamber without breaking the vacuum.

24. The apparatus of claim 22, wherein each of the purification mechanism and the nitrification mechanism includes:
a microwave generation unit for generating a microwave;
a planar antenna provided with a number of slots; and
a microwave transmission mechanism for transmitting the microwave generated from the microwave generation unit to the planar antenna,
wherein the radicals are generated by converting a processing gas into a plasma by means of inducing the microwave provided from the planar antenna into the single chamber.

25. The apparatus of claim 22, wherein each of the purification mechanism and the nitrification mechanism includes a catalyst provided in the single chamber, and the catalyst is heated to a high temperature and is to be in contact with a processing gas, and the radicals are generated in the single chamber when the processing gas contacts the catalyst.

26. The apparatus of claim 17, further comprising:
a first chamber incorporating therein the purification mechanism and the Si infiltration mechanism;
a second chamber incorporating therein the nitrification mechanism; and
a transfer mechanism for transferring the semiconductor substrate between the first chamber and the second chamber without breaking the vacuum.

27. The apparatus of claim 18, further comprising:
a first chamber incorporating therein the purification mechanism and the Si infiltration mechanism;
a second chamber incorporating therein the nitrification mechanism and the dielectric film formation mechanism; and
a transfer mechanism for transferring the semiconductor substrate between the first chamber and the second chamber without breaking the vacuum.

28. The apparatus of claim 17, further comprising:
a plurality of chambers incorporating therein the individual mechanisms, respectively; and
a transfer mechanism for transferring the semiconductor substrate between the chambers without breaking the vacuum.

29. A computer-readable storage medium for storing therein a computer-executable control program for controlling a processing apparatus, wherein, when executed, the control program controls the processing apparatus to perform the semiconductor device manufacturing method disclosed in claim 1.
